(19) United States
(12) Patent Application Publication
(10) Pub. No.: US 2023/0005722 A1
(43) Pub. Date: Jan. 5, 2023

(54) PLASMA PROCESSING APPARATUS AND PLASMA PROCESSING METHOD

(71) Applicant: Tokyo Electron Limited, Minato-ku, Tokyo (JP)

(72) Inventor: Yasuaki TANIIKE, Nirasaki City, Yamanashi (JP)

(21) Appl. No.: 17/756,980

(22) PCT Filed: Dec. 2, 2020
(86) PCT No.: PCT/JP2020/044903

§ 371 Date: Jun. 7, 2022

(30) Foreign Application Priority Data
Dec. 16, 2019 (JP) 2019-226625

(51) Int. Cl. H01J 37/32; C23C 16/509

(52) U.S. Cl. CPC H01J 37/32568; H01J 37/32082; C23C 16/509; H01J 2237/3321

(57) ABSTRACT

A plasma processing apparatus is provided. The plasma processing apparatus is provided with an upper electrode, a lower electrode, and an electromagnetic wave emission port. The upper electrode is provided so as to allow discharging a processing gas into a processing container. The lower electrode is provided so as to holding a workpiece in the processing container. The electromagnetic wave emission port is provided at a height position between a height position of the upper electrode and a height position of the lower electrode, and is open toward a center of the processing container.

### TECHNICAL FIELD

An exemplary embodiment of the present disclosure relates to a plasma processing apparatus and a plasma processing method.

### BACKGROUND

Patent Document 1 discloses a plasma processing apparatus that emits electromagnetic waves downward through an insulator. Patent Document 2 discloses a structure of an upper electrode that has an outer portion including a semiconductor and a central portion including a dielectric.

### PRIOR ART DOCUMENTS

### Patent Documents

Patent Document 1: Japanese Laid-Open Patent Publication No. 2007-214589
Patent Document 2: Japanese Laid-Open Patent Publication No. 2000-323456

A plasma processing apparatus and a plasma processing method capable of improving in-plane uniformity of plasma are expected.

### SUMMARY

In an exemplary embodiment, a plasma processing apparatus is provided. The plasma processing apparatus includes an upper electrode, a lower electrode, and an electromagnetic wave emission port. The upper electrode is provided to be capable of ejecting a processing gas into a processing container. The lower electrode is provided to be capable of holding a workpiece in the processing container. The electromagnetic wave emission port is provided at a height position between a height position of the upper electrode and a height position of the lower electrode, and is open toward the center of the processing container.

With a plasma processing apparatus and a plasma processing method according to an exemplary embodiment, it is possible to improve in-plane uniformity of plasma.

### BRIEF DESCRIPTION OF DRAWINGS

FIG. 1 is a view illustrating a vertical cross-sectional configuration of a plasma processing apparatus according to an exemplary embodiment.

FIG. 2 is a view illustrating a vertical cross-sectional configuration of a portion in a vicinity of an electromagnetic wave emission port.

FIG. 3 is a view illustrating a vertical cross-sectional configuration of a plasma processing apparatus according to a comparative example.

FIG. 4 is a graph showing a relationship between a distance r and normalized plasma power P_{A}.

FIG. 5 is a graph showing a relationship between a distance r and normalized plasma power P_{A}.

FIG. 6 is a graph showing a relationship between L/D and normalized plasma power P_{B}.

FIG. 7 is a view illustrating a vertical cross-sectional configuration around a dielectric ring of a plasma processing apparatus according to an exemplary embodiment.

FIG. 8 is a view illustrating a vertical cross-sectional configuration around a dielectric ring of a plasma processing apparatus according to an exemplary embodiment.

FIG. 9 is a view illustrating a vertical cross-sectional configuration around a dielectric ring of a plasma processing apparatus according to an exemplary embodiment.

FIG. 10 is a view illustrating an exemplary configuration for applying a bias to a lower electrode.

### DETAILED DESCRIPTION

Hereinafter, various exemplary embodiments will be described.

In an exemplary embodiment, a plasma processing apparatus is provided. The plasma processing apparatus includes an upper electrode, a lower electrode, and an electromagnetic wave emission port. The upper electrode is provided to be capable of ejecting a processing gas into a processing container. The lower electrode is provided to be capable of holding a workpiece in the processing container. The electromagnetic wave emission port is provided at a height position between a height position of the upper electrode and a height position of the lower electrode, and is open toward a center of the processing container.

Electromagnetic waves are emitted from the electromagnetic wave emission port, and travel toward the center of the processing container. By absorbing energy of the electromagnetic waves, the processing gas in the processing container is plasmarized. Since the electromagnetic waves propagate in a horizontal direction, plasma intensity in a horizontal plane is likely to be more uniform compared to a case of propagating in a vertical direction.

When the electromagnetic wave emission port extends along a circumferential direction of the processing container, plasma intensity in the circumferential direction becomes uniform. However, since the electromagnetic waves travel toward the center, the electromagnetic waves are superimposed and plasma intensity increases at the center. Therefore, it is desired to reduce intensity of the electromagnetic waves at the center.

In an exemplary embodiment, a groove for electromagnetic wave reflection is formed on a lower surface of an outer peripheral portion of the upper electrode. When the groove is formed on the lower surface of the outer peripheral portion, electromagnetic waves not only travel in the horizontal direction but also travel into the groove, and are reflected at a deep portion of the groove. In this case, a ratio at which the electromagnetic waves are absorbed increases immediately below the groove, and the plasma intensity in the outer peripheral portion increases. Thus, the plasma intensity at the center decreases due to energy consumption in the outer peripheral portion. Therefore, uniformity of the plasma intensity in a radial direction of the processing container increases.

In an exemplary embodiment, the groove includes an inside inner peripheral surface, an outside inner peripheral surface facing the inside inner peripheral surface, and a bottom surface located in the deep portion of the groove and connecting the inside inner peripheral surface and the outside inner peripheral surface. The electromagnetic waves that have traveled into the groove are reflected by the inside inner peripheral surface and the bottom surface.

In an exemplary embodiment, the outside inner peripheral surface is flush with an inner peripheral surface of a side wall of the processing container. When the outside inner peripheral surface and the inner peripheral surface have a step therebetween rather than being flush with each other, electric fields due to the electromagnetic waves are concentrated to the stepped portion. Electric field concentration may cause an unintended discharge or an increase of plasma intensity. When the outside inner peripheral surface and the inner peripheral surface are flush with each other, it is possible to suppress such a phenomenon.

In an exemplary embodiment, a corner portion is formed between the inside inner peripheral surface of the groove and a lower open end surface of the groove, and the corner portion has a roundness in a vertical cross section along the radial direction of the processing container. When the electromagnetic waves propagate toward the center of the processing container, it is likely that the corner portion of the groove inhibits smooth traveling of the electromagnetic waves. When the corner portion has a roundness (rounded shape), it is possible to improve the in-plane uniformity of plasma intensity by suppressing the inhibition of traveling of electromagnetic waves by the corner portion.

In an exemplary embodiment, the groove is disposed above a region outward of a workpiece placement region in the lower electrode. That is, since the plasma intensity tends to be high immediately below the groove, it is possible to improve the uniformity of the plasma intensity on the workpiece by setting the position of the groove away from the workpiece.

In an exemplary embodiment, it is desirable that a depth L and a width D of the groove satisfy 0.3≤L/D≤1.0. When this condition is satisfied, the in-plane uniformity of plasma intensity is increased.

In an exemplary embodiment, it is desirable that the depth L and the width D of the groove satisfy 0.4≤L/D≤0.9. When this condition is satisfied, the in-plane uniformity of plasma intensity is further increased.

In an exemplary embodiment, the plasma processing apparatus includes a gas introduction port on an inner surface of the groove. The processing gas can be introduced even into a place where the groove exists, and a concentration distribution and convection of the processing gas in the processing container can be controlled. Therefore, since these parameters can be controlled, it is possible to control a distribution of plasma more precisely.

In an exemplary embodiment, the plasma processing apparatus further includes a dielectric ring including a cylindrical upper dielectric and a ring-shaped lower dielectric continuous to a lower portion of the upper dielectric, and the electromagnetic wave emission port is configured by an inner surface of the ring-shaped lower dielectric. The electromagnetic waves emitted from the dielectric ring have high uniformity in the circumferential direction, and the uniformity of plasma intensity in the circumferential direction increases. The electromagnetic waves introduced from the upper dielectric travels in the ring-shaped lower dielectric toward the inner surface (inner tip surface) thereof. In the process of traveling in the lower dielectric, directions of electric fields due to the electromagnetic waves are aligned.

In an exemplary embodiment, a dimension obtained by subtracting a radial width of the upper dielectric of the dielectric ring from a radial width of the lower dielectric of the dielectric ring is 5 mm to 30 mm. That is, when the dimension is 5 mm or more, the directions of the electric fields due to the electromagnetic waves are aligned. When the dimension exceeds 30 mm, the directions of the electric fields are aligned, but the intensity of electromagnetic waves is attenuated or the size of the apparatus is enlarged.

In an exemplary embodiment, a corner portion is formed between an outer surface and a lower surface of the lower dielectric of the dielectric ring, and the corner portion has a roundness in a vertical cross section along the radial direction of the processing container. In the case where the corner portion has a roundness (rounded shape), when the electromagnetic waves move from the upper dielectric to the lower dielectric, the electromagnetic waves can travel more smoothly than in the case where there is no roundness.

In an exemplary embodiment, a lower surface of the upper electrode and a top surface of the lower dielectric of the dielectric ring are at the same height. That is, although the electromagnetic waves are emitted from below the top surface of the lower dielectric of the dielectric ring, since the lower surface of the upper electrode and the top surface of the lower dielectric are at the same height, there is no stepped portion due to a difference in height therebetween. Thus, it is possible to suppress an unintended discharge or an increase in plasma intensity.

In an exemplary embodiment, a plasma processing method is provided. The plasma processing method includes a process of disposing a workpiece on the lower electrode of any one of the above-described plasma processing apparatuses, a process of supplying a processing gas from the upper electrode into the processing container, and a process of introducing electromagnetic waves from the electromagnetic wave emission port into the processing container.

According to this method, it is possible to increase the in-plane uniformity of plasma by using the above-described plasma processing apparatuses, and thus it is possible to execute plasma processing with high in-plane uniformity on the workpiece.

Hereinafter, various exemplary embodiments will be described in detail with reference to the drawings. In addition, the same reference numerals are designated to the same or corresponding parts in each drawing, and duplicate description will be omitted.

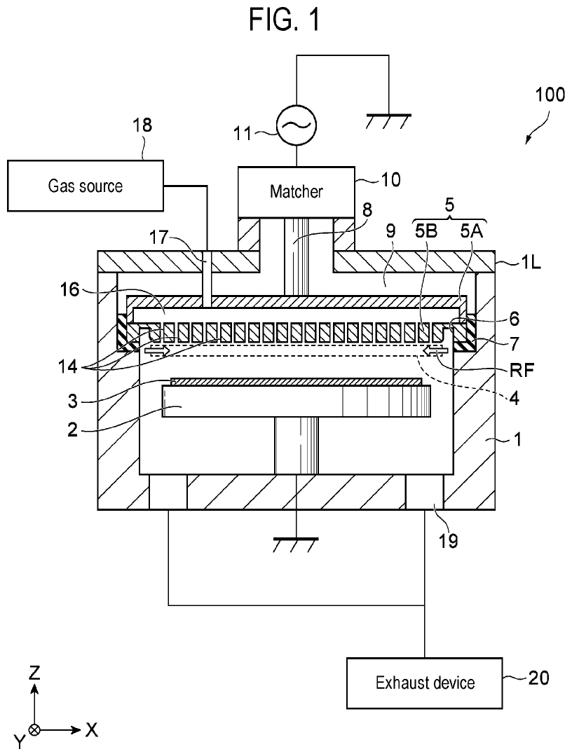

FIG. 1 is a view illustrating a vertical cross-sectional configuration of a plasma processing apparatus according to an exemplary embodiment.

A plasma processing apparatus 100 includes a processing container 1 having an upper opening, a lid 1L that seals the upper opening of the processing container 1, a stage 2 (lower electrode, stage) disposed in the processing container 1, and a plasma generation source located above the stage 2. The plasma generation source includes an upper electrode 5 disposed to face the stage 2 and a dielectric ring 7 having an electromagnetic wave emission port (radio-frequency wave emission port). Electromagnetic waves RF are emitted from a side end surface of a lower portion of the dielectric ring 7 toward a center of the processing container 1. The dielectric ring 7 is an electromagnetic wave (radio-frequency wave) introducer, and a step (lip) having an annular top surface is formed in an upper portion of an inner wall surface of the processing container 1. The dielectric ring 7 is engaged with this step so that the dielectric ring 7 is disposed on and supported by the top surface of the step. The dielectric ring 7 is fit along an entire circumference of the processing container 1. The electromagnetic wave emission port defined on an inner tip surface of the dielectric ring 7 is formed over the entire circumference of the processing container 1 in a circumferential direction.

A workpiece (substrate 3) is disposed on the stage 2. The substrate 3 is not particularly limited as long as it is subjected to plasma processing, and examples thereof include a semiconductor substrate, a dielectric substrate such as glass or alumina (Al₂O₃), a metallic substrate, or the like.

A gas inside the processing container 1 can be exhausted to the outside by an exhaust device 20 via a gas exhaust port 19. A processing gas is supplied from a gas source 18 into the processing container 1 via a supply pipe 17. Specifically, the upper electrode 5 has a shower structure including a processing gas diffusion part (internal space 16), and the supply pipe 17 penetrates the lid 1L, extends across a waveguide 9, and is connected to an interior of the internal space 16. The processing gas introduced into the internal space 16 is supplied to the interior of the processing container 1 via a plurality of processing gas outlets (gas holes 14) formed in a lower region of the upper electrode 5. The upper electrode 5 of this example has a shower plate structure made of metal, and includes the internal space 16 into which the processing gas is introduced and the gas holes 14 which make the internal space 16 and an internal space of the processing container 1 communicate with each other. The upper electrode 5 includes an upper metallic member 5A having a recess on a lower surface thereof and a lower metallic member 5B having the gas holes 14, and the internal space 16 is formed in the recess disposed between these metallic members.

The waveguide 9 is formed among the upper electrode 5, a lower surface of the lid 1L, and an inner surface of the processing container 1. Electromagnetic waves (e.g., electromagnetic waves such as VHF waves and UHF waves having a frequency higher than frequencies of short-waves), which are input from a first radio-frequency power supply 11 to a space above the upper electrode 5 via a first radio-frequency matcher 10 and an antenna 8, radially travel in the horizontal direction through the waveguide 9. When reaching the inner surface of the processing container 1, the electromagnetic waves travel downward, pass through the interior of the dielectric ring 7 to be emitted from the inner tip surface of the lower portion of the dielectric ring 7, and travel horizontally toward a central axis of the processing container 1.

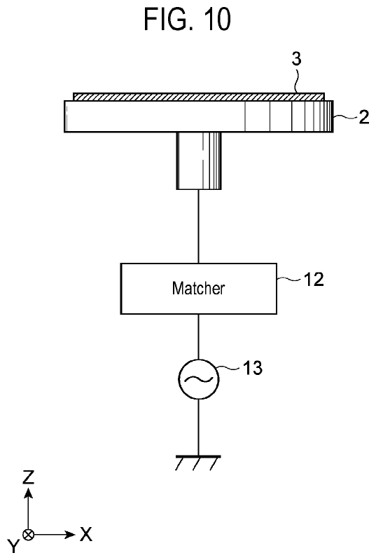

When the processing gas is introduced into the processing container 1 and the electromagnetic waves are introduced into the processing container 1 in a state in which the interior of the processing container 1 is depressurized by the exhaust device 20 to a pressure at which plasma can be generated, plasma is generated below the upper electrode 5. A plasma region 4 is located directly below the upper electrode 5. In addition, one end of the first radio-frequency power supply 11 is connected to the first radio-frequency matcher 10, and the other end of the first radio-frequency power supply 11 is connected to the ground. In addition, as the antenna 8, any antenna may be used as long as it can transmit electromagnetic waves such as VHF waves, and as an electromagnetic wave transmission component, a coaxial cable may be used in addition to the waveguide. In addition, in this example, the stage 2 is electrically connected to the ground, but it is also possible to apply radio-frequency waves or the like to the stage 2 (see FIG. 10).

In the processing container 1, it is assumed that the central axis extending in a vertical direction is a Z axis, an axis perpendicular to the Z axis is an X axis, and an axis perpendicular to both the Z axis and the X axis is a Y axis. In this case, an XY plane constitutes a horizontal plane. A central axis of the dielectric ring 7 coincides with the vertical central axis (the Z axis) of the processing container 1. The plasma region 4 is located directly below the upper electrode 5 and is located in the horizontal plane including the inner tip portion of the lower portion of the dielectric ring 7.

The upper electrode 5 has a circular planar shape when viewed from above, and a position of the center thereof coincides with a position of the central axis (the Z axis) in the vertical direction of the processing container 1. An annular recess (the groove 6) is formed on a lower surface of the upper electrode 5 as needed. The groove 6 is formed in an annular shape to surround the central axis of the processing container 1, and has an annular planar shape when viewed from below.

The groove 6 is disposed above a region outward of the workpiece placement region in the lower electrode (a diameter of the substrate 3 is 300 mm). That is, since the plasma intensity tends to be high immediately below the groove 6, it is possible to improve the uniformity of the plasma intensity on the substrate 3 by setting the position of the groove 6 away from the substrate 3. In this example, the groove 6 is disposed above a region outward of the stage 2.

As described above, the plasma processing apparatus 100 according to the embodiment includes the upper electrode 5, the lower electrode (the stage 2), and the electromagnetic wave emission port (the inner tip surface of the lower portion of the dielectric ring 7). The upper electrode 5 is provided with the plurality of gas holes 14 to be capable of ejecting the processing gas into the processing container 1. The lower electrode (the stage 2) is provided to be capable of holding the workpiece in the processing container 1.

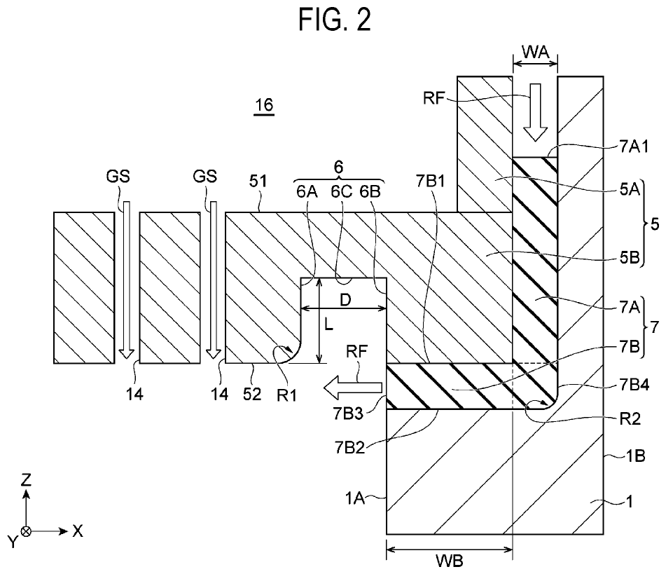

FIG. 2 is a view illustrating a vertical cross-sectional configuration of a portion in a vicinity of the electromagnetic wave emission port.

An inner tip surface 7B3 of the lower portion of the dielectric ring 7 constitutes the electromagnetic wave emission port. The inner tip surface 7B3 is provided at a height position between a height position (a position in the Z-axis direction) of the upper electrode 5 and a height position (a position in the Z-axis direction) of the lower electrode, and is open toward the center of the processing container 1. Electromagnetic waves RF are emitted from the electromagnetic wave emission port, and travel toward the center of the processing container 1. By absorbing the energy of the electromagnetic waves RF, the processing gas in the processing container 1 is plasmarized. Since the electromagnetic waves RF propagate in the horizontal direction, it is possible to suppress generation of a higher-order mode compared with a case of propagating in the vertical direction, so that the plasma intensity in the horizontal plane (particularly in the circumferential direction) is likely to be more uniform.

The electromagnetic wave emission port (the tip surface 7B3) extends along the circumferential direction of the processing container 1, and the plasma intensity in the circumferential direction becomes uniform. Since the electromagnetic waves RF travel toward the center of the processing container 1, the electromagnetic waves are superimposed and the plasma intensity increases at the center. Therefore, it is desired to reduce intensity of electromagnetic waves in the center.

The groove 6 for electromagnetic wave reflection is formed on the lower surface of the outer peripheral portion of the upper electrode 5. When the groove 6 is formed on the lower surface of the outer peripheral portion, the electromagnetic waves RF not only travel in the horizontal direction but also travel into the groove 6, and are reflected at the deep portion of the groove 6. In this case, the ratio at which the electromagnetic waves are absorbed increases immediately below the groove 6. Thus, the plasma intensity in the outer peripheral portion increases, and the plasma intensity at the center decreases due to energy consumption in the outer peripheral portion. Therefore, the uniformity of the plasma intensity in the radial direction of the processing container 1 increases.

The groove 6 includes an inside inner peripheral surface 6A, an outside inner peripheral surface 6B facing the inside inner peripheral surface 6A, and a bottom surface 6C located in the deep portion of the groove 6 and connecting the inside inner peripheral surface 6A and the outside inner peripheral surface 6B. The electromagnetic waves RF that have traveled into the groove 6 are reflected by the inside inner peripheral surface 6A and the bottom surface 6C.

The outside inner peripheral surface 6B of the groove 6 is flush with an inner peripheral surface 1A of a side wall of the processing container 1 (i.e., positions thereof in the radial direction are the same). When the outside inner peripheral surface 6B and the inner peripheral surface 1A have a step therebetween rather than being flush with each other, there is a problem in that electric fields due to electromagnetic waves are concentrated to the stepped portion. Simply providing a groove creates an edge (a position where electric fields are concentrated). Electric field concentration may cause an unintended discharge or an increase of plasma intensity. When the outside inner peripheral surface and the inner peripheral surface are flush with each other, it is possible to suppress such a problem.

In addition, since the plasma intensity in the groove 6 becomes high, it is desirable that the groove 6 is located far from the substrate in the horizontal direction (radial direction). This makes it possible to suppress diffusion of plasma toward the center of the processing container 1. By providing the groove 6 in the outside of the substrate placement region, it is possible to broaden a gas hole forming region outward.

A first corner portion R1 is formed between the inside inner peripheral surface 6A of the groove 6 and a lower opening end surface 52 of the groove 6. As illustrated in FIG. 2, the first corner portion R1 has a roundness in the vertical cross section along the radial direction of the processing container 1. When the electromagnetic waves RF propagate toward the center of the processing container 1, it is likely that the first corner portion R1 of the groove 6 inhibits smooth travel of the electromagnetic waves RF. When the first corner portion R1 has a roundness (rounded shape), it is possible to suppress the inhibition of traveling of electromagnetic waves by the first corner portion R1 and improve the in-plane uniformity of plasma intensity. A radius of curvature of the first corner portion R1 in the vertical cross section is 50% or less of a width D and a depth L of the groove 6. When the width D of the groove 6 is 10 mm, the radius of curvature is 5 mm or less. However, when the radius of curvature is too small, there is no effect, and when the radius of curvature is too large, electromagnetic wave energy absorbed by the processing gas in the peripheral portion becomes small. Therefore, from the viewpoints of suppressing the inhibition of traveling of electromagnetic waves and absorbing energy, the radius of curvature of the first corner portion R1 in the vertical cross section is desirably 1 mm to 5 mm, and more specifically 1 mm to 3 mm. In this example, a diameter of the upper electrode 5 is 320 mm to 360 mm, the diameter of the substrate as a workpiece is 300 mm, and an inner diameter of the processing container 1 is 350 mm to 380 mm.

The dielectric ring 7 includes a cylindrical upper dielectric 7A and a ring-shaped lower dielectric 7B continuous to a lower portion of the upper dielectric 7A. The upper dielectric 7A and the lower dielectric 7B are formed integral with each other. The electromagnetic wave emission port is configured with the inner surface (the tip surface 7B3) of the ring-shaped lower dielectric 7B. The electromagnetic waves RF emitted from the dielectric ring 7 have high uniformity in the circumferential direction, and thus the uniformity of the plasma intensity in the circumferential direction becomes high. The electromagnetic waves RF introduced from the upper dielectric 7A travel in the ring-shaped lower dielectric 7B toward the inner surface thereof. In the process of traveling in the lower dielectric 7B, directions of electric fields due to the electromagnetic waves RF are aligned.

A width WB obtained by subtracting a radial width WA of the upper dielectric 7A from a radial width (WB+WA) of the lower dielectric 7B of the dielectric ring 7 is 5 mm to 30 mm. That is, when the width WB is 5 mm or more, the directions of electric fields due to electromagnetic waves RF are aligned. When the width WB exceeds 30 mm, the directions of electric fields are aligned, but the intensity of electromagnetic waves is attenuated or the apparatus is enlarged

Electromagnetic waves RF are introduced from a top surface 7A1 of the upper dielectric 7A of the dielectric ring 7 and travel downward. A second corner portion R2 is formed between an outer side surface 7B4 and a lower surface 7B2 of the lower dielectric 7B of the dielectric ring 7. The second corner portion R2 has a roundness in the vertical cross section along the radial direction of the processing container 1. In the case in which the second corner portion R2 has a roundness (rounded shape), when the electromagnetic waves RF move from the upper dielectric 7A to the lower dielectric 7B, the electromagnetic waves can travel more smoothly compared to the case where there is no roundness. When the roundness is too large, a path of the electromagnetic waves RF becomes narrow so that it becomes difficult for the electromagnetic waves to propagate. From the viewpoint of smooth traveling of the electromagnetic waves, a radius of curvature of the second corner portion R2 in the vertical cross section is desirably 0.5 mm to 3 mm, and more specifically 1 mm to 2 mm.

A height of the lower opening end surface 52 of the groove 6 and the top surface 7B1 of the lower dielectric 7B of the dielectric ring 7 are the same (positions in the Z-axis direction are the same). That is, the electromagnetic waves RF are emitted from below the top surface 7B1 of the lower dielectric 7B of the dielectric ring 7, but the lower opening end surface 52 (the lower surface of the upper electrode) of the groove 6 and the top surface 7B1 of the lower dielectric 7B have the same height. Therefore, there is no stepped portion due to a difference in height between the lower opening end surface 52 and the top surface 7B1, so that it is possible to suppress an unintended discharge and an increase in plasma intensity.

The processing container 1 includes the inner peripheral surface 1A and an outer peripheral surface 1B. An annular step is provided in the inner peripheral surface 1A, and the lower surface 7B2 of the lower dielectric 7B of the dielectric ring 7 is located on the top surface of the step. The top surface of the stepped portion and an inner cylindrical surface of a side wall continuous upward from the top surface are connected to each other via the roundness corresponding to the second corner portion R2 in the vertical cross section. A material of the dielectric ring 7 is, for example, Al₂O₃, but other dielectric materials such as quartz glass may also be used. A materials of the processing container 1 and the upper electrode 5, which are in contact with the dielectric ring 7, are metal. As the metallic materials, iron, stainless steel, aluminum, or the like may be used.

The upper electrode 5 includes the internal space 16 as a processing gas diffusion part. The gas holes 14 extend from a top surface 51 of the lower metallic member 5B that defines a lower side of the internal space 16, to the lower surface 52 of the lower metallic member 5B. A processing gas GS introduced into the internal space 16 is supplied to a region below the upper electrode 5 via the plurality of gas holes 14. The electromagnetic waves (e.g., VHF waves) emitted from the tip surface 7B3 are turned into surface waves while giving energy to the supplied processing gas GS, and travel toward the central axis of the processing container 1 along the lower surface of the upper electrode 5.

By adjusting the depth L (a depth in the Z-axis direction) of the groove 6 and the width D (a distance in the radial direction) of the groove 6, it is possible to further improve the in-plane uniformity of plasma intensity. The depth L may be set to 0 mm or more and 20 mm or less, and the width D may be set to 0 mm or less and 20 mm or less. In an example in which the groove 6 does not exist, the depth L=0 mm. Even in the case where the groove 6 does not exist, it is possible to improve the in-plane uniformity of plasma intensity compared with a comparative example. The details will be described below.

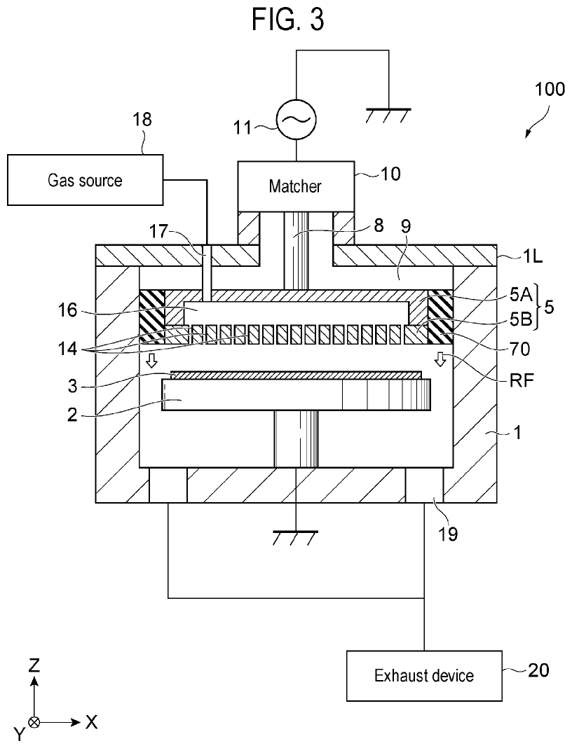

FIG. 3 is a view illustrating a vertical cross-sectional configuration of a plasma processing apparatus according to a comparative example.

A plasma processing apparatus 100 illustrated in FIG. 3 is provided with a dielectric cylinder 70 that abuts on the outer peripheral surface of the upper electrode 5 in place of the dielectric ring 7 of FIG. 1. The electromagnetic waves RF are introduced from a top surface of the dielectric cylinder 70 and emitted downward from a bottom surface thereof. The upper electrode 5 does not include a groove. Except for these points, the plasma processing apparatus 100 of the comparative example illustrated in FIG. 3 is the same as the plasma processing apparatus illustrated in FIG. 1.

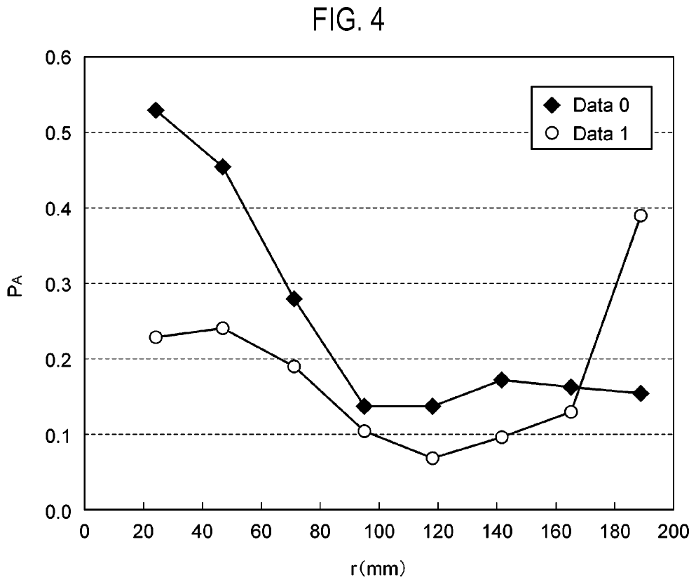

FIG. 4 is a graph showing a relationship between a distance r from the center of the processing container and normalized plasma power P_{A}.

It is assumed that the normalized plasma power P_{A} is defined as power Pₗₒₛₛ absorbed by the processing gas with respect to power Pᵢₙ input from a radio-frequency power supply to the plasma processing apparatus (P_{A}=Pₗₒₛₛ/Pᵢₙ).

Data 0 represents data in the case of the plasma processing apparatus according to the comparative example illustrated in FIG. 3, and Data 1 represents data in the case of the plasma processing apparatus according to a first example. In the first example (Data 1), the plasma processing apparatus of FIG. 1 does not include the groove 6.

As illustrated in FIG. 4, in the case of the comparative example (Data 0), the power P_{A} of the plasma in a vicinity of the center becomes significantly higher than that in the peripheral portion. On the other hand, in the case of the first example (Data 1), the power P_{A} of the plasma in a vicinity of the center becomes lower than that in the peripheral portion. The distance r as each measurement point on the graph is r=23.75 mm, r=47.5 mm, r=71.25 mm, r=95 mm, r=118.75 mm, r=142.5 mm, r=166.25 mm, and r=190 mm.

In the comparative example (top plasma), since electromagnetic waves are introduced from an upper electrode surface, a dimension of the electrode becomes small so that an introduction range of the processing gas cannot be secured sufficiently. From the viewpoint of plasma uniformity, it is not desirable that the dielectric cylinder 70 is used and a distance between the upper electrode 5 and the substrate 3 is too close as in the comparative example. In the plasma processing apparatus according to the embodiment (side plasma), electromagnetic waves in the VHF band are introduced from a side wall adjacent to the upper electrode 5 along a direction perpendicular to the side wall. As a result, since an outside diameter of the upper electrode 5 can be increased without changing a size of the processing container 1, it is possible to broaden a plasma generation region and an introduction range of the processing gas. Even in the case of a side plasma configuration without having a groove (first example), it is possible to broaden the plasma generation region and the introduction range of the processing gas compared with the comparative example. In addition, in the case of the comparative example, arrangement of the gas supply pipe 17 formed on a propagation path of the electromagnetic waves or the like has an influence, so that the plasma uniformity in the circumferential direction is lowered. On the other hand, in the case of the embodiment, the uniformity of the plasma intensity in the circumferential direction becomes higher than that in the comparative example.

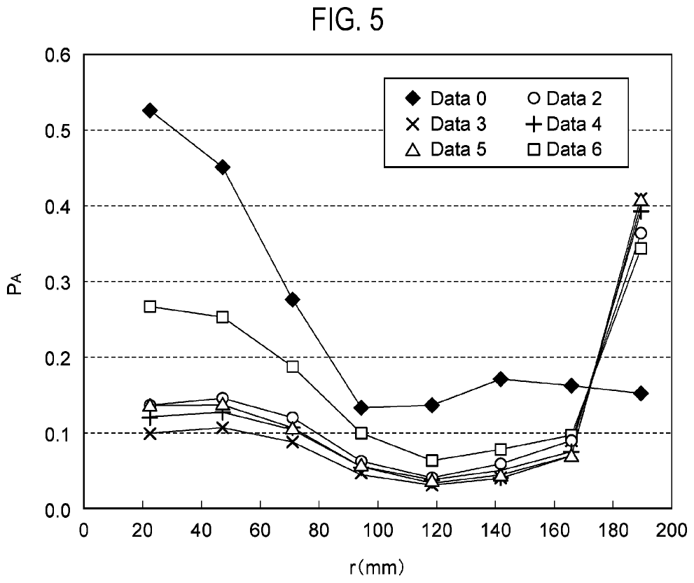

FIG. 5 is a graph showing a relationship between a distance r from the center of the processing container and normalized plasma power P_{A}.

A definition of the normalized plasma power P_{A} is the same as that in FIG. 4. Data 0 is data in the case of the above-described comparative example. Assuming that a ratio of the depth L and the width D of the groove 6 in the plasma processing apparatus of FIG. 1 is R_{A}=L/D, in a second example (Data 2), R_{A}=L/D=0.25. Similarly, in a third embodiment (Data 3), R_{A}=L/D=0.5. In a fourth embodiment (Data 4), R_{A}=L/D=0.75. In a fifth embodiment (Data 5), R_{A}=L/D=1.0. In a sixth embodiment (Data6), R_{A}=L/D=2.0.

Specifically, in the second example, L=5 mm and D=20 mm. In the third embodiment, L=8 mm and D=16 mm. In the fourth embodiment, L=6 mm and D=8 mm. In the fifth embodiment, L=8 mm and D=8 mm. In the sixth embodiment, L=20 mm and D=10 mm. In addition, the distance r as each measurement point on the graph is r=23.75 mm, r=47.5 mm, r=71.25 mm, r=95 mm, r=118.75 mm, r=142.5 mm, r=166.25 mm, and r=190 mm.

As shown from the second example (Data 2) to the sixth example (Data 6), when the ratio R_{A}=L/D is changed from 0.25 to 2.0, it can be recognized that when R_{A}=L/D=0.5 in the third embodiment (Data 3), the power of plasma P_{A} in a vicinity of the center becomes small. Therefore, it can be recognized that flatness of power distribution in the radial direction becomes high.

From this point of view, it is desirable that the depth L of the groove 6 (the depth in the Z-axis direction) and the width D of the groove 6 (the distance in the radial direction) satisfy the following conditions.

0.25≤R_{A}=L/D≤2.0

0.25≤R_{A}=L/D≤1.0

0.25≤R_{A}=L/D≤0.75

0.5≤R_{A}=L/D≤0.75

According to the graphs of FIGS. 4 and 5, the plasma intensity in the peripheral portion is high, but it is sufficient to make the plasma intensity uniform in at least a region where the substrate is present, for example, in a region having a diameter of 300 mm (a region having a radius r of 150 mm). That is, in such a case, even when the plasma intensity is high in the peripheral portion, it is considered that plasma processing is not significantly affected.

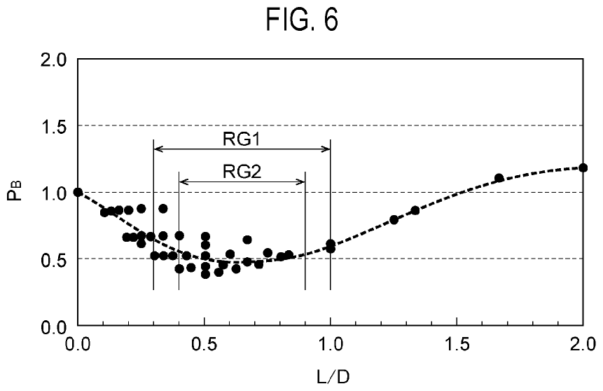

FIG. 6 is a graph showing a relationship between L/D and normalized plasma power P_{B}.

The normalized plasma power P_{B} is defined as power Pᵣ absorbed by a processing gas in a plasma processing apparatus having a groove with respect to power Pᵣₗ absorbed by a processing gas in a plasma processing apparatus without having the groove 6 (P_{B}=Pᵣ/Pᵣₗ). In addition, this graph shows data in the case of a region in a vicinity of the center (r=23.75 mm). When there is no groove, data (L, D)=(0, 1) (unit is mm) was set to (L/D=0). In addition, a value of L was changed within a range of 2 mm to 20 mm, and a value of D was changed within a range of 6 mm to 20 mm. Each data (L, D) (unit is mm) is as follows.

(L, D)=(0, 1). (L, D)=(2, 6), (2, 8), (2, 10), (2, 12), (2, 14), (2, 16), (2, 18), (2, 20). (L, D)=(4, 6), (4, 8), (4, 10), (4, 12), (4, 14), (4, 16), (4, 18), (4, 20). (L, D)=(5, 10), (5, 20). (L, D)=(6, 6), (6, 8), (6, 10), (6, 12), (6, 14), (6, 16), (6, 18), (6, 20). (L, D)=(8, 6), (8, 8), (8, 10), (8, 12), (8, 14), (8, 16), (8, 18), (8, 20). (L, D)=(10, 6), (10, 8), (10, 10), (10, 12), (10, 14), (10, 16), (10, 18), (10, 20). (L, D)=(20, 10), (20, 20).

As can be seen from FIG. 6, in order to reduce the plasma power P_{B} in a region in the vicinity of the center, it is desirable that the depth L of the groove 6 and the width D of the groove satisfy 0.3≤L/D≤1.0 (a range RG1). When this condition is satisfied, power of the plasma in the region in the vicinity of the center decreases, and in-plane uniformity of plasma intensity increases. In addition, it is desirable that the depth L of the groove 6 and the width D of the groove satisfy 0.4≤L/D≤0.9 (a range RG2). When this condition is satisfied, the power of the plasma in the region in the vicinity of the center decreases, and the in-plane uniformity of the plasma intensity further increases.

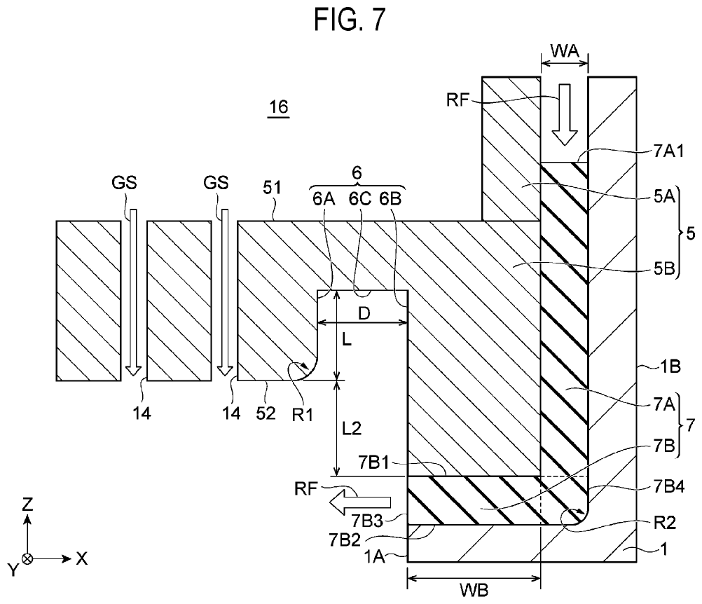

FIG. 7 is a view illustrating a vertical cross-sectional configuration around a dielectric ring of a plasma processing apparatus according to an exemplary embodiment.

The top surface 7B1 of the lower portion of the dielectric ring 7 illustrated in FIG. 2 is located in the same plane as the lower surface 52 of the upper electrode 5. The plasma processing apparatus illustrated in FIG. 7 has a configuration in which the lower dielectric 7B of the dielectric ring 7 illustrated in FIG. 2 is shifted downward, and other configurations are the same as those illustrated in FIG. 2. The top surface 7B1 of the lower dielectric 7B is located below the lower surface 52 of the upper electrode 5 by a distance L2. As a result, the inner tip surface 7B3 (the electromagnetic wave emission port) of the lower dielectric 7B is located lower than that in the case of FIG. 2. This configuration is effective when it is desired to separate a plasma generation position from the upper electrode 5. In addition, the outside inner peripheral surface 6B of the groove 6 is located at the same position in the radial direction as the inner tip surface 7B3 of the dielectric ring 7, such that the outside inner peripheral surface 6B and the inner tip surface 7B3 are flush with each other. With this configuration, it is possible to suppress concentration of unnecessary electric fields.

In the configuration of FIG. 7, an introduction position of the electromagnetic waves is separated from the position of the lower surface 52 of the upper electrode 5 along the height direction. As a result, the plasma intensity is suppressed from being biased in the radial direction. The electromagnetic wave emission port may be located at any height as long as it is located between the position of the lower surface 52 of the upper electrode 5 and a front surface of the stage 2.

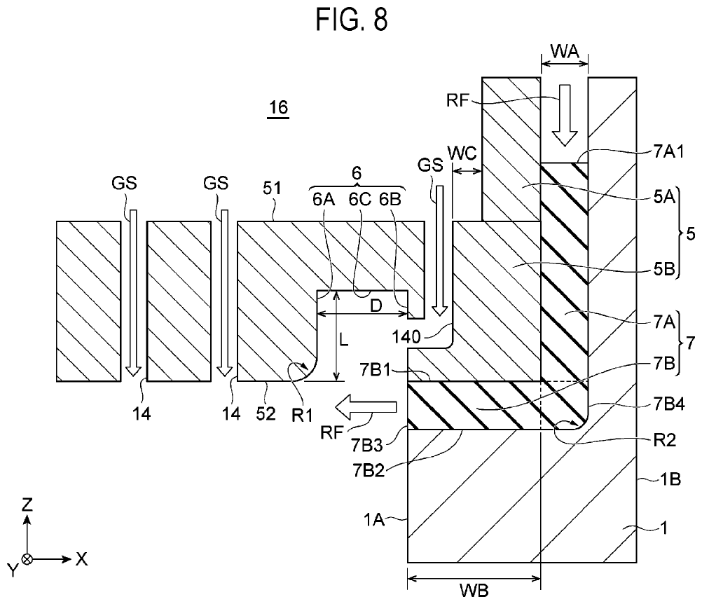

FIG. 8 is a view illustrating a vertical cross-sectional configuration around a dielectric ring of a plasma processing apparatus according to an exemplary embodiment.

The plasma processing apparatus illustrated in FIG. 8 has a configuration in which an auxiliary gas hole 140 is formed on the inner surface of the groove 6 illustrated in FIG. 2, and other configurations are the same as those illustrated in FIG. 2.

That is, this plasma processing apparatus is provided with a gas introduction port (the auxiliary gas hole 140) in the inner surface of the groove 6. With this configuration, since the processing gas GS via the auxiliary gas hole 140 can be introduced even into a place where the groove 6 is present, it is possible to control a concentration distribution or convection of the processing gas in the processing container 1. Therefore, since parameters such as the concentration distribution and convection can be controlled, it is possible to control the plasma distribution more precisely. The auxiliary gas hole 140 is formed in the lower metallic member 5B of the upper electrode 5. The auxiliary gas hole 140 is a through-hole extending from the top surface 51 of the lower metallic member 5B to the inner surface of the groove 6. A planar shape of this through-hole is polygonal or circular, but it may also be formed in an arcuate shape.

A position where the auxiliary gas hole 140 is formed is set such that the shortest distance from the inner surface of the side wall of the upper metallic member 5A is a distance WC. The distance WC is, for example, 0 mm to 30 mm. The processing gas is introduced into and diffused in the internal space 16. At this time, when there is a gas flow along the inner surface of the upper metallic member 5A, a resistance to introduction of the processing gas into the auxiliary gas hole 140 decreases as the distance WC decreases. Therefore, in such a case, in order to efficiently introduce the processing gas into the auxiliary gas hole 140, the distance WC may be set to 0 mm. Since it is good to separate the position of the groove 6 constituting the recess from a substrate to be processed, the position of the auxiliary gas hole 140, which is located outward of the groove 6, affects a dimension of the processing container in the radial direction. When the distance WC is set to 0 mm, it is possible to reduce the size of the apparatus in the radial direction. In other words, for example, when the auxiliary gas hole 140 having an arcuate planar shape is used, the inner surface of the side wall of the upper metallic member 5A and an outside inner surface of the auxiliary gas hole 140 are flush with each other.

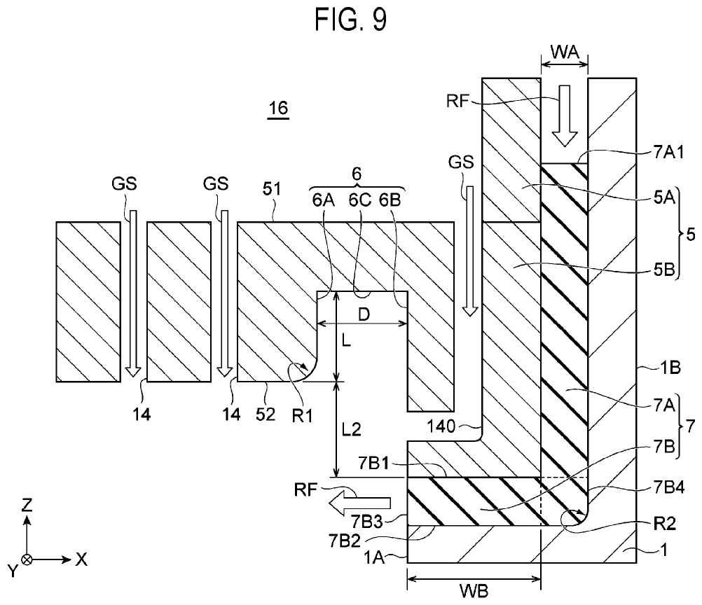

FIG. 9 is a view illustrating a vertical cross-sectional configuration around a dielectric ring of a plasma processing apparatus according to an exemplary embodiment.

The plasma processing apparatus illustrated in FIG. 9 has a configuration in which the auxiliary gas hole 140 illustrated in FIG. 8 is provided outward of the groove 6 in the plasma processing apparatus illustrated in FIG. 7, and the other configurations are the same as those illustrated in FIG. 7. In this embodiment, an example in which the separation distance WC of the auxiliary gas hole 140 in FIG. 8 is set to 0 mm is illustrated, but it is also possible to set the distance WC to be within the same range as in the case of FIG. 8.

Since the dimension of the upper dielectric 7A in the dielectric ring 7 is longer than that in the case of FIG. 8 and the auxiliary gas hole 140 is provided outward of the groove 6, a length of the auxiliary gas hole 140 in the Z-axis direction is longer than that in the case of FIG. 8. By using the auxiliary gas hole 140, since parameters such as the concentration distribution and convection can be controlled, so that it is possible to control the plasma distribution more precisely.

The configurations of FIGS. 8 and 9 are provided with outlets (gas holes) that allow the processing gas to be discharged in two directions in a vertical cross section. The gas holes may be provided only on the surface of the upper electrode 5 or only on the side wall.

FIG. 10 is a view illustrating an exemplary configuration for applying a bias to a lower electrode.

In the above-described plasma processing apparatuses, the stage 2 may also be connected to a second radio-frequency power supply 13 via a second radio-frequency matcher 12. A frequency of the second radio-frequency power supply 13 may be different from that of the first radio-frequency power supply 11 illustrated in FIG. 1. With this configuration, since two frequencies can be used for plasma generation, types of controlling the electric fields in the internal space of the processing container are increased so that the in-plane distribution of plasma intensity can be controlled more precisely.

The frequency of the second radio-frequency power supply 13 may be set to be lower than the frequency of the first radio-frequency power supply 11 (e.g., 2 MHz). This may function as an ion assist structure that draws ions in the plasma to a side of the substrate. This configuration is applicable to the above-described plasma processing apparatuses.

A plasma processing method of the present disclosure includes a process of disposing a workpiece on the stage 2 (the lower electrode) in any one of the above-described plasma processing apparatuses, and a process of supplying a processing gas from the upper electrode 5 into the processing container 1. The method further includes a process of introducing electromagnetic waves into the processing container 1 from the electromagnetic wave emission port (the inner tip surface of the lower portion of the dielectric ring 7). According to this plasma processing method, since the in-plane uniformity of plasma can be improved by using the above-described plasma processing apparatuses, it is possible to execute plasma processing with high in-plane uniformity on the workpiece.

As an example of the plasma processing method, a pressure in the processing container is set to 0.1 Torr (13.33 Pa), and a pressure in the waveguide is set to 760 Torr (1013 hPa). A frequency of the first radio-frequency power supply 11 is set to 220 MHz, an output of the first radio-frequency power supply 11 is set to 1000 W, a distance between the substrate 3 and the upper electrode 5 is set to 60 mm, the depth L of the groove 6 is set to 6 mm, and the width D of the groove is set to 8 mm. As the plasma processing, an etching process and a deposition process are known. As etching gases of a SiO₂ film or a Si₃N₄ film to be processed, CF, CF₃, C₂F₂, CO, SiF₆, SiCF, and the like are known. As a gas used for the deposition process such as plasma CVD, in the case of forming a Si-containing film, a silane-based gas (SiH₄, Si₂H₆) or the like may be used. When forming a film of a Si-containing compound (e.g., a silicon nitride), a gas including a raw material (e.g., nitrogen) of the compound may be further used.

Although a frequency of the VHF band is illustrated as an example in the above-described embodiments, another frequency may be used as the frequency of the radio-frequency power supply. A frequency of the short wave (HF) band is 3 MHz to 30 MHz, and a wavelength thereof is 100 m to 10 m. A frequency of the VHF band is 30 MHz to 300 MHz, and a wavelength thereof is 10 m to 1 m. A frequency of the UHF band, which is included in the microwave band, is 300 MHz to 3 GHz and a wavelength thereof is 1 m to 10 cm. Radio-frequency waves in the VHF band tend to propagate on a surface of an electrode, especially, in a waveguide. Surface waves propagate from a peripheral edge portion of the lower surface of the upper electrode 5 toward a central portion. In the case of such a frequency band, it is effective to form the groove 6 in order to improve the uniformity of plasma intensity in the radial direction.

That is, when a frequency becomes high, a wavelength becomes short. Thus, it is likely that antinodes and nodes of electric fields corresponding to the wavelength are generated along the radial direction of the processing container and the electric field distribution becomes non-uniform. In particular, plasma density in the center portion of the upper electrode 5 becomes higher than plasma density in the peripheral portion. In the central portion, a resistivity of plasma becomes low, so that a current tends to concentrate and non-uniformity of the electric field distribution tends to be further strengthened.

On the other hand, by forming the groove 6 (a recess) on the upper electrode surface in the vicinity of the electromagnetic wave introduction port in the dielectric ring 7, the effect of reflecting the electromagnetic waves and a labyrinth effect are produced. Thus, the electric fields of VHF waves introduced from the dielectric ring 7 are suppressed from being transmitted to the surface of the upper electrode 5. Therefore, it is possible to selectively increase the plasma density in the peripheral portion of the processing container. As a result, it is possible to reduce biasing of the electric field distribution on the substrate 3 and to perform uniform plasma processing over the entire substrate 3.

A plasma processing apparatus is an apparatus capable of performing a good reaction at a relatively low temperature. The above-described plasma processing apparatuses may be used for various types of plasma processing apparatuses such as a parallel plate type plasma processing apparatus. The plasma processing includes processes such as etching, sputtering, and deposition such as chemical vapor deposition (CVD), and the apparatuses according to the embodiments may be used for any process. When a gap between the upper electrode and the lower electrode is narrow, capacitively coupled plasma (CCP) is generated. On the other hand, when this gap is wide, plasma is generated in an upper space of the processing container (a chamber). It is known that the minimum value of the gap of a plasma processing apparatus is 9 mm to 13 mm. In addition, it may be considered that uniformity is improved by providing a dielectric on the lower surface of the upper electrode 5 to change a wavelength, but in this case, a distance between the electrodes changes. The above-described plasma processing apparatuses are particularly effective in a configuration in which surface wave plasma is generated.

In recent years, with the miniaturization of design rules, high-density plasma processing is expected. The above-described plasma generation mechanism using radio frequency waves in the VHF band or the UHF band are useful for high-density plasma processing. The plasma processing apparatuses according to the embodiments have advantages in that the in-plane uniformity of plasma intensity can be enhanced, the outside diameter of the upper electrode 5 can be increased, and the plasma generation region and the introduction range of the processing gas can be increased.

Although various exemplary embodiments have been described above, various omissions, substitutions, and changes may be made without being limited to the above-described exemplary embodiments. In addition, elements in different embodiments may be combined to form other embodiments. From the foregoing description, it should be understood that various embodiments of the present disclosure have been described herein and various modifications can be made without departing from the scope and spirit of the present disclosure. Accordingly, the various embodiments disclosed herein are not intended to be limiting, and the true scope and gist thereof are set forth by the appended claims.

### EXPLANATION OF REFERENCE NUMERALS

1: processing container, 1A: inner peripheral surface, 1B: outer peripheral surface, 1L: lid, 2: stage, 3: substrate, 4: plasma region, 5: upper electrode, 5A: upper metallic member, 5B: lower metallic member, 6: groove, 6A: inside inner peripheral surface, 6B: outside inner peripheral surface, 6C: bottom surface, 7: dielectric ring, 7A: upper dielectric, 7A1: top surface, 7B: lower dielectric, 7B1: top surface, 7B2: lower surface, 7B3: tip surface, 7B4: outer surface, 8: antenna, 9: waveguide, 10: first radio-frequency matcher, 11: first radio-frequency power supply, 12: second radio-frequency matcher, 13: second radio-frequency power supply, 14: gas hole, 16: internal space, 17: supply pipe, 18: gas source, 19: gas exhaust port, 20: exhaust device, 51: top surface, 52: lower opening end surface (lower surface), 70: dielectric cylinder, 100: plasma processing apparatus, 140: auxiliary gas hole, GS: processing gas, R1: first corner portion, R2: second corner portion, RF: electromagnetic wave

1-14. (canceled)

15. A plasma processing apparatus comprising:
an upper electrode configured to eject a processing gas into a processing container;
a lower electrode configured to hold a workpiece in the processing container; and
an electromagnetic wave emission port provided at a height position between a height position of the upper electrode and a height position of the lower electrode, wherein the electromagnetic wave emission port is open toward a center of the processing container.

16. The plasma processing apparatus of claim 15, further comprising a groove for electromagnetic wave reflection, wherein the groove is formed on a lower surface of an outer peripheral portion of the upper electrode.

17. The plasma processing apparatus of claim 16, wherein the groove includes:
an inside inner peripheral surface;
an outside inner peripheral surface facing the inside inner peripheral surface; and
a bottom surface located in a deep portion of the groove and connecting the inside inner peripheral surface and the outside inner peripheral surface.

18. The plasma processing apparatus of claim 17, wherein the outside inner peripheral surface is flush with an inner peripheral surface of a side wall of the processing container.

19. The plasma processing apparatus of claim 18, wherein a first corner portion is formed between the inside inner peripheral surface of the groove and a lower open end surface of the groove, and the first corner portion has a roundness in a vertical cross section along a radial direction of the processing container.

20. The plasma processing apparatus of claim 19, wherein the groove is disposed above a region outward of a workpiece placement region in the lower electrode.

21. The plasma processing apparatus of claim 20, wherein a depth L and a width D of the groove satisfy 0.3≤L/D≤1.0.

22. The plasma processing apparatus of claim 21, further comprising a gas introduction port on an inner surface of the groove.

23. The plasma processing apparatus of claim 22, further comprising a dielectric ring, which includes a cylindrical upper dielectric and a ring-shaped lower dielectric continuous to a lower portion of the upper dielectric,
wherein the electromagnetic wave emission port is configured by an inner surface of the ring-shaped lower dielectric.

24. The plasma processing apparatus of claim 23, wherein a dimension obtained by subtracting a radial width of the upper dielectric of the dielectric ring from a radial width of the lower dielectric of the dielectric ring is 5 mm to 30 mm.

25. The plasma processing apparatus of claim 24, wherein a second corner portion is formed between an outer surface and a lower surface of the lower dielectric of the dielectric ring, and the second corner portion has a roundness in a vertical cross section along the radial direction of the processing container.

26. The plasma processing apparatus of claim 25, wherein a lower surface of the upper electrode and a top surface of the lower dielectric of the dielectric ring have the same height.

27. The plasma processing apparatus of claim 23, wherein a second corner portion is formed between an outer surface and a lower surface of the lower dielectric of the dielectric ring, and the second corner portion has a roundness in a vertical cross section along the radial direction of the processing container.

28. The plasma processing apparatus of claim 17, wherein a corner portion is formed between the inside inner peripheral surface of the groove and a lower open end surface of the groove, and the corner portion has a roundness in a vertical cross section along a radial direction of the processing container.

29. The plasma processing apparatus of claim 17, wherein the groove is disposed above a region outward of a workpiece placement region in the lower electrode.

30. The plasma processing apparatus of claim 16, wherein a depth L and a width D of the groove satisfy 0.3≤L/D≤1.0.

31. The plasma processing apparatus of claim 16, wherein a depth L and a width D of the groove satisfy 0.4≤L/D≤0.9.

32. The plasma processing apparatus of claim 16, further comprising a gas introduction port on an inner surface of the groove.

33. The plasma processing apparatus of claim 15, further comprising a dielectric ring, which includes a cylindrical upper dielectric and a ring-shaped lower dielectric continuous to a lower portion of the upper dielectric,
wherein the electromagnetic wave emission port is configured by an inner surface of the ring-shaped lower dielectric.

34. A plasma processing method comprising:
placing the workpiece on the lower electrode in the plasma processing apparatus of claim 15;
supplying the processing gas from the upper electrode into the processing container; and
introducing electromagnetic waves into the processing container from the electromagnetic wave emission port.
